(19) United States
(12) Patent Application Publication
(10) Pub. No.: US 2021/0242039 A1
(43) Pub. Date: Aug. 5, 2021

(54) SUBSTRATE PROCESSING SYSTEM AND METHOD TO REDUCE A NUMBER OF EXTERNAL CONNECTORS PROVIDED ON THE SYSTEM

(71) Applicant: Tokyo Electron Limited, Tokyo (JP)

(72) Inventor: Melvin Verbaas, Yamanashi (JP)

(21) Appl. No.: 17/166,047

(22) Filed: Feb. 3, 2021

Related U.S. Application Data
(60) Provisional application No. 62/969,719, filed on Feb. 4, 2020.

(51) Int. Cl. H01L 21/67; B05C 11/10; B05C 5/02

(52) U.S. Cl. CPC H01L 21/67023; B05C 5/0225; B05C 11/1026

(57) ABSTRACT

Embodiments of substrate processing systems and methods are provided for reducing the number of external connectors provided on a substrate processing system for receiving liquids and gases from external liquid and gas sources. In one embodiment, a substrate processing system includes a plurality of processing units for processing a substrate; a plurality of external connectors for receiving liquids and/or gases from a plurality of sources stored outside of the substrate processing system; and a plurality of internal distribution lines for routing the liquids and/or gases from the external connectors to the processing units. The disclosed substrate processing system reduces the number of external connectors provided on the system by: (a) including only one external connector for each liquid and gas source, and (b) providing a plurality of internal distribution lines within the substrate processing system for routing liquids and gases from the external connectors to the processing units.

This application claims priority to U.S. Provisional Patent Application No. 62/969,719, entitled, “DIELECTRIC ETCH STOP LAYER FOR REACTIVE ION ETCH (RIE) LAG REDUCTION AND CHAMFER CORNER PROTECTION,” filed Feb. 4, 2020; the disclosure of which is expressly incorporated herein, in its entirety, by reference.

### BACKGROUND

The present disclosure relates to the substrate processing systems or tools used to process substrates. In particular, it provides systems and methods to reduce the number of external connectors, which are provided on the system for supplying liquid(s) and/or gas(es) to a plurality of processing units or modules included within the system.

Some substrate processing systems contain a plurality of processing units or modules within the system housing for performing one or more processing steps on a substrate. For example, a substrate processing system may contain a separate processing unit for performing any of a wide variety of process steps of a substrate processing flow, including without limitation, etch steps, deposition steps, sputtering steps, coating steps, developing steps, baking steps, etc. The processing units contained within the system may be arranged alongside any of a wide variety of substrate movement mechanisms, including for example, but not limited to, a track used to transfer the substrate to/from processing units, a main arm mechanism used to transfer substrates into/out of the processing units, etc., all as is well known to those skilled in the art.

Some of the processing units contained within a substrate processing system may dispense a liquid onto a surface of a substrate, while other processing units may dispense a gas into a processing space to invoke a reaction between the gas and a layer or film formed on the substrate surface, and still others may utilize both liquids and gases. For example, some processing units may apply liquids to a surface of a substrate to form layers or films, such as spin-on hard masks, imaging layers (photoresist), and anti-reflective coating layers (e.g., silicon anti-reflective coating (SiARC), topcoat antireflective (TARC) layers, bottom anti-reflective coating (BARC) layers, etc.), on the substrate surface. Other processing units may utilize a processing gas dispensed into the processing unit to perform a substrate processing step, such as, for example an etch step, deposition step, oxidation step, sputtering step, etc.

Conventional substrate processing systems often include a plurality of external connectors on the backside (or the top or bottom) of the system for each liquid and gas supplied to the processing units. More specifically, an individual external connector is typically provided on the backside (or the top or bottom) of the system for each liquid and gas supplied to the each of the processing units. In addition, mechanisms and chambers used for transferring substrates between processing units may also include dedicated gas connectors.

FIG. 1 (PRIOR ART) depicts a backside of an exemplary conventional substrate processing system 100 containing a plurality of processing units 110 for processing a substrate. It will be recognized that the system of FIG. 1 is merely exemplary and conventional processing systems may be configured in a wide variety of manners. In the substrate processing system 100 shown in FIG. 1, the processing units 110 are stacked vertically and arranged around a cylindrical supporting body 120. Within the cylindrical supporting body 120, a liftable substrate transporting system 130 is provided and used to transport a substrate to/from one or more of the processing units 110 contained within the system.

As noted above, liquids and/or gases may be used within at least a subset of the processing units 110 to perform a process on a substrate. For example, liquids (such as, a resist solution, a develop solution, a quench solution, a rinse solution, a deposition solution, an etch solution, etc.) may be used to perform processing steps. Further, processing gases (such as for example, but not limited to, nitrogen, argon, hydrogen, helium, oxygen, ammonia, chlorine, dichlorosilane, hydrogen chloride, hydrogen fluoride, silicon tetrachloride, fluorocarbons, etc.) may be used to perform substrate processing steps. The liquids and gases supplied to, and used within, the processing units 110 are often stored and provided from outside of, and external to, the substrate processing system 100 (e.g., within one or more liquid source cabinets, gas cabinets, gas panels, gas sources, etc.), routed through various liquid and gas inlet pipes, valves, and/or sensors, and connected to external connectors provided on the backside (or the top or bottom) the substrate processing system 100

As shown in FIG. 1, for example, a plurality of external connectors are provided on the backside of the substrate processing system 100 for receiving liquids and gases, which may be supplied to the system from external liquid and gas sources. In the illustrated system, external connectors 140 and external connectors 150 are provided on the backside of the substrate processing system 100 for receiving three different gases and two different liquids, respectively (or vice versa). For drawing clarity, a different cross-hatching is used to represent each connector coupled to receive a different gas or liquid and the external connectors of each processing unit 110 are not separately labeled with reference numbers.

In the substrate processing system 100 shown in FIG. 1, a separate external connector 140 and/or external connector 150 is provided on the backside of the system for each liquid and gas supplied to for each module or unit which uses a particular gas or liquid. Thus, for example, a separate external gas and/or external liquid connector is provided for each liquid and gas individually supplied to each of the processing units 110. Specifically, the substrate processing system 100 shown in FIG. 1 is depicted as including, up to sixty-five (65) external connectors on the backside of the system—five external connectors (i.e., three external gas connectors 140 and two external liquid connectors 150) for supplying liquids and gases to various transfer mechanisms and chambers, and five external connectors for supplying liquids and gases to each of the processing units 110. Although each processing unit 110 is coupled for receiving liquids and gases from all five external connectors 140/150, it will be recognized by those skilled in the art that some of the processing units 110 may include only a subset of these connectors (or none at all).

Regardless of the number of external connectors 140 and external connectors 150 included for each processing unit 110, conventional substrate processing systems, such as the system shown in FIG. 1, typically include a large number of external connectors for connecting the various liquids and gasses to the system. This is undesirable for a number of reasons.

One problem that arises in substrate processing systems having a large number of external connectors is that a high installation cost is typically associated with each external connector provided on the system, due to the components (e.g., liquid/gas distribution pipes, valves, sensors, filters etc.) and installation labor required to connect external liquid and gas sources to the connectors. Further, the use of additional components increase the costs and time associated with equipment maintenance. It would, therefore, be beneficial to reduce the number of individual liquid/gas connectors provided on the processing system to reduce the installation costs, maintenance costs and installation/maintenance time associated therewith.

Another problem that arises in substrate processing systems having a large number of external connectors is in controlling the liquid/gases supplied to each of the individual processing units. In the substrate processing system 100 shown in FIG. 1, for example, a separate controller may be coupled to each processing unit 110 to control the flow rates, pressures, etc., of the liquids/gases supplied to the processing unit 110. When separate controllers are used, differences in controller offsets may cause problems with chamber to chamber matching. Further, the liquids/gases supplied to the external connectors 140/150 may be contained within small vessels, which require frequent replacement and may result in an inconsistent supply of liquids/gases over the lifetime of the system. It would, therefore, be beneficial to centralize the control of liquids/gases supplied to the processing units and reduce the number of supply vessels coupled to the substrate processing system.

### SUMMARY

Various embodiments of substrate processing systems and methods are disclosed herein for reducing the number of external connectors, which are provided on the substrate processing system for receiving one or more liquids and/or gases from external liquid and gas sources. Similar to conventional substrate processing systems, a substrate processing system in accordance with the present disclosure may generally include a plurality of processing units for processing a substrate, and a plurality of external connectors for receiving one or more liquids and/or gases from a plurality of liquid and gas sources, which are stored outside of the substrate processing system. Unlike conventional substrate processing systems, the substrate processing system disclosed herein reduces the number of external connectors provided on the system by: (a) including only one external connector for each liquid and gas source, and (b) providing a plurality of internal distribution lines within the substrate processing system for routing the one or more liquids and/or gases from the plurality of external connectors to the plurality of processing units.

In addition to improving the installation and maintenance costs and time, such techniques also provide a variety of technical benefits. By reducing number of external connectors, for example, the disclosed substrate processing system enables fewer gas and liquid sources to be used, and further enables bulk supply vessels to be used instead of a plurality of smaller supply vessels. This allows for a more consistent liquid and gas supply with less frequent source changes. For example, the incoming gas pressure provided to the system from a bulk gas supply vessel may be more tightly controlled through the use of a single gas regulator. Further, in the case of toxic or flammable liquids, a number of smaller individual liquid sources or bottles may be reduced. This allows for a more constant liquid flow supply and less frequent source changes, both factors which provide improved safety when operating and maintaining the substrate processing system.

In addition to reducing number of external connectors, the disclosed substrate processing system is provided with a centralized controller, which uses sensor feedback to control the supply of liquids and gases to the substrate processing system. By utilizing a centralized controller, the disclosed substrate processing system improves chamber to chamber matching by eliminating differences in controller offsets that tend to occur when separate controllers are used to control the supply of liquid and gases to the individual processing units.

According to one embodiment, a substrate processing system may generally include a plurality of external connectors, a plurality of processing units and a plurality of internal distribution lines. The plurality of external connectors are provided on the substrate processing system for receiving one or more liquids and/or gases that are supplied from a plurality of sources, which are stored outside of the substrate processing system, to the plurality of external connectors via a plurality of external supply lines. In some embodiments, the plurality of external connectors may be provided on a backside of the substrate processing system. In other embodiments, the plurality of external connectors may be provided on a top, bottom or other locations of the substrate processing system. In the present disclosure, only one external connector is provided on the substrate processing system for each of the plurality of sources to reduce installation costs and time and reduce operating and maintenance costs.

The plurality of processing units are each coupled to receive at least one of the one or more liquids and/or gases for processing a substrate. The plurality of internal distribution lines are provided within the substrate processing system for routing the one or more liquids and/or gases from the plurality of external connectors to the plurality of processing units. In the present disclosure, a separate one of the plurality of internal distribution lines is provided within the substrate processing system for each of the plurality of external connectors.

In some embodiments, the plurality of internal distribution line may each be coupled to route a first liquid or a first gas from one of the plurality of external connectors to all of the processing units contained within the substrate processing system. In some embodiments, the plurality of internal distribution lines may each be coupled to route a first liquid or a first gas from one of the plurality of external connectors to one or more of the processing units contained within the substrate processing system. In some embodiments, the plurality of internal distribution lines may each be coupled to route a first liquid or a first gas from one of the plurality of external connectors to only the processing units that utilize the first liquid or the first gas to process the substrate.

In some embodiments, the substrate processing system disclosed herein may receive one or more liquids and one or more gases from the plurality of sources stored outside of the substrate processing system. In some embodiments, the one or more liquids may include one or more of a resist solution, a develop solution, a quench solution, a rinse solution, a deposition solution, and an etch solution. Likewise, the one or more gases may include one or more of nitrogen, argon, hydrogen, helium, oxygen, ammonia, chlorine, dichlorosilane, hydrogen chloride, hydrogen fluoride, silicon tetrachloride, and fluorocarbons.

In some embodiments, the substrate processing system may further include a plurality of sensors and a centralized controller. The plurality of sensors may be coupled to monitor the one or more liquids and/or gases supplied from the plurality of sources and generate sensor data based on said monitoring. In some embodiments, the plurality of sensors may be coupled to one or more of: (a) the plurality of external supply lines, or the plurality of external connectors, for monitoring the one or more liquids and/or gases supplied from the plurality of sources to the plurality of external connectors, and (b) the plurality of internal distribution lines for monitoring the one or more liquids and/or gases routed from the plurality of external connectors to the plurality of processing units.

The centralized controller may be coupled to receive the sensor data from the plurality of sensors, and may be configured to use the sensor data to control supply of the one or more liquids and/or gases to the plurality of external connectors and/or to the plurality of processing units. In some embodiments, the centralized controller may use the sensor data to control a flow rate or a pressure of the one or more liquids and/or gases supplied to each processing unit, based on liquid/gas supply needs of the processing unit. In other embodiments, the centralized controller may use artificial intelligence to control supply of the one or more liquids and/or gases to the plurality of processing units based on the sensor data received from the plurality of sensors.

According to another embodiment, a method is provided herein to reduce a number of external connectors provided on a substrate processing system having a plurality of processing units. In general, the method may include providing the substrate processing system with the plurality of processing units, wherein each processing unit uses a liquid and/or a gas to process a substrate, and providing a plurality of external connectors on the substrate processing system for receiving one or more liquids and/or gases from a plurality of sources stored outside of the substrate processing system. In the disclosed method, however, only one external connector may be provided on the substrate processing system for each of the plurality of sources to reduce installation costs and time and reduce operating and maintenance costs.

In some embodiments, the method may further include providing a plurality of internal distribution lines within the substrate processing system for routing the one or more liquids and/or gases from the plurality of external connectors to the plurality of processing units. In some embodiments, said providing the plurality of internal distribution lines may include providing a separate internal distribution line within the substrate processing system for each external connector.

In some embodiments, the method may include coupling each of the internal distribution lines to all of the processing units contained within the substrate processing system. In other embodiments, the method may include coupling each of the internal distribution lines to one or more of the processing units contained within the substrate processing system. In yet other embodiments, the method may include coupling each internal distribution line, so as to route a first liquid or a first gas from one of the plurality of external connectors to only the processing units that utilize the first liquid or the first gas to process the substrate.

In some embodiments, the method may further include providing the substrate processing system with a plurality of sensors and a centralized controller. In such embodiments, the method may further include monitoring the one or more liquids and/or gases supplied from the plurality of sources and generating sensor data based on said monitoring, wherein said monitoring and generating are performed by the plurality of sensors. In addition, the method may include receiving the sensor data from the plurality of sensors and using the sensor data to control supply of the one or more liquids and/or gases to the plurality of external connectors and/or to the plurality of processing units, wherein said receiving the sensor data and using the sensor data are performed by the centralized controller. In some embodiments, the method may further include using the sensor data to predict and control supply of the one or more liquids and/or gases to the plurality of external connectors over time and/or based liquid/gas supply needs of the plurality of processing units.

According to another embodiment, a method is provided herein to couple a substrate processing system to a plurality of liquid and gas sources, which are stored outside of the substrate processing system. The method may generally include arranging the substrate processing system within a facility, and coupling the plurality of liquid and gas sources to a plurality of external connectors, which are provided on the substrate processing system for receiving liquids and gases from the liquid and gas sources. In some embodiments of the disclosed method, the substrate processing system may include a plurality of processing units, but only one external connector for each of the plurality of liquid and gas sources to reduce installation costs and time and reduce operating and maintenance costs.

In some embodiments, said coupling may include coupling, via an external supply line, each of the plurality of liquid and gas sources to a different one of the plurality of external connectors for supplying a liquid or a gas thereto. In some embodiments, said coupling may include coupling one or more sensors to the external supply line for monitoring the liquid or the gas supplied to the different one of the plurality of external connectors.

In some embodiments, the method may further include providing a plurality of internal distribution lines within the substrate processing system for routing one or more liquids and gases from the plurality of external connectors to the plurality of processing units. In some embodiments, the method may further include coupling one or more sensors to each of the plurality of internal distribution lines for monitoring the one or more liquids and gases routed from the plurality of external connectors to the plurality of processing units.

### BRIEF DESCRIPTION OF THE DRAWINGS

A more complete understanding of the present inventions and advantages thereof may be acquired by referring to the following description taken in conjunction with the accompanying drawings, in which like reference numbers indicate like features. It is to be noted, however, that the accompanying drawings illustrate only exemplary embodiments of the disclosed concepts and are therefore not to be considered limiting of the scope, for the disclosed concepts may admit to other equally effective embodiments.

FIG. 1 (PRIOR ART) is a back view of a conventional substrate processing system comprising a plurality of processing units, where a separate external connector is provided on the backside of the system for each liquid and gas supplied to the transfer module and for each liquid and gas individually supplied to each of the processing units;

FIG. 2 is a top view of a substrate processing system, in accordance with the present disclosure, including a plurality of processing units and only one external connector for each liquid source and gas source coupled to the system;

FIG. 3 is a front view of the substrate processing system shown in FIG. 1;

FIG. 4 is a partially cut-away back view of the substrate processing system shown in FIG. 1 taken along line 3-3, depicting internal distribution lines routed within the system between one of the external connectors and each of the plurality of processing units;

FIG. 5 is a flowchart diagram illustrating one embodiment of a method to reduce a number of external connectors provided on a substrate processing system having a plurality of processing units; and

FIG. 6 is a flowchart diagram illustrating one embodiment of a method to couple a substrate processing system to a plurality of liquid and gas sources.

### DETAILED DESCRIPTION

Various embodiments of substrate processing systems and methods are disclosed herein for reducing the number of external connectors, which are provided on the substrate processing system for receiving liquids and gases from external liquid and gas sources. Similar to conventional substrate processing systems, a substrate processing system in accordance with the present disclosure may generally include a plurality of processing units for processing a substrate, and a plurality of external connectors for receiving liquids and gases from a plurality of liquid and gas sources, which are stored outside of the substrate processing system. Unlike conventional substrate processing systems, the substrate processing system disclosed herein reduces the number of external connectors provided on the system by: (a) including only one external connector for each liquid and gas source, and (b) providing a plurality of internal distribution lines within the substrate processing system for routing liquids and gases from the plurality of external connectors to the plurality of processing units.

In addition to improving the installation and maintenance costs and time, such techniques also provide a variety of technical benefits. By reducing number of external connectors, the disclosed substrate processing system enables fewer gas and liquid sources to be used, and further enables bulk supply vessels to be used instead of a plurality of smaller supply vessels. This allows for a more consistent liquid and gas supply with less frequent source changes. For example, the incoming gas pressure provided to the system from a bulk gas supply vessel may be more tightly controlled through the use of a single gas regulator. Further, in the case of toxic or flammable liquids, a number of smaller individual liquid sources or bottles may be reduced. This allows for a more constant liquid flow supply and less frequent source changes, both factors which provide improved safety when operating and maintaining the substrate processing system.

In addition to reducing number of external connectors, the disclosed substrate processing system is provided with a centralized controller, which uses sensor feedback to control the supply of liquids and gases to the substrate processing system. By utilizing a centralized controller, the disclosed substrate processing system improves chamber to chamber matching by eliminating differences in controller offsets that tend to occur when separate controllers are used to control the supply of liquid and gases to the individual processing units.

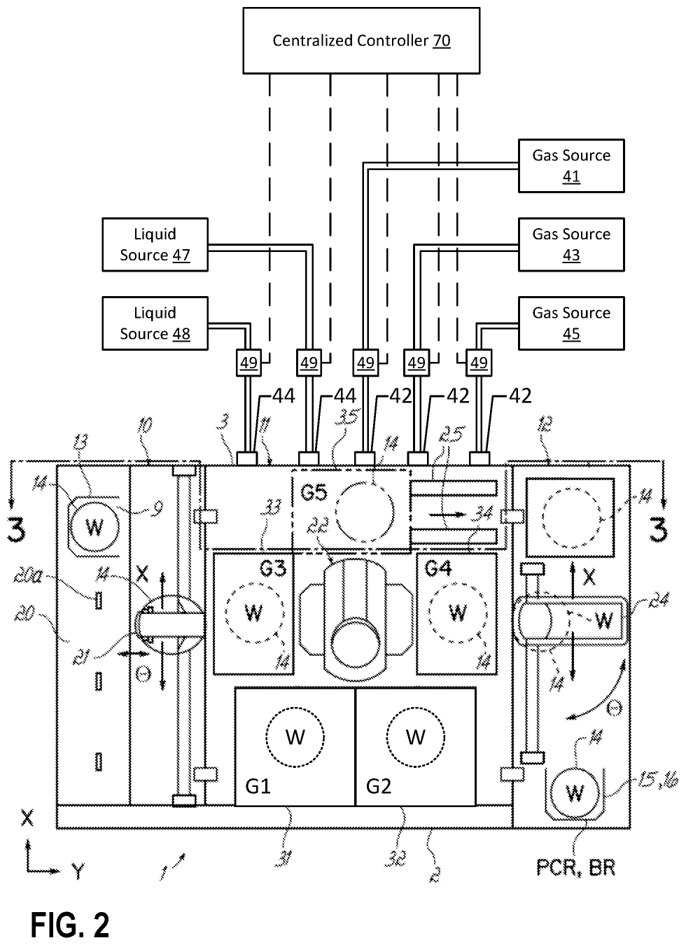

FIGS. 2-4 illustrate one example of a substrate processing system 1 in which the liquid/gas distribution techniques described herein may be incorporated. As shown in FIGS. 2-4, substrate processing system 1 may include various components for processing substrates (e.g., semiconductor wafers) including one or more components that apply various liquids and/or gases to substrates for processing purposes.

It will be recognized that the substrate processing system 1 shown in FIGS. 2-4 is merely one example substrate processing system in which the liquid/gas distribution techniques described herein may be used. As such, the disclosure of the processing system shown in FIGS. 2-4 is not meant to be limiting, but rather merely representative of one example processing system having a reduced set of external connectors for receiving liquids and/or gases supplied to the system, and internal distribution lines for distributing the liquids and/or gases to various processing system components. Further, though the processing system depicted in FIGS. 2-4 is described with reference to a system for processing substrates (e.g., semiconductor wafers), it will be recognized that the techniques described herein may be utilized with other types of substrates and/or in other processing systems that utilize liquids and/or gases in multiple processing units. Thus, it will be recognized that the techniques described herein may be utilized with a wide range of processing systems that apply liquids and/or gases to a wide range of substrates.

As shown in FIGS. 2-4, substrate processing system 1 may generally include a load/unload section 10, a process section 11, and an interface section 12. The load/unload section 10 has a cassette table 20 on which cassettes 13, each storing a plurality of semiconductor wafers (W) 14 (e.g., 25), are loaded and unloaded from the substrate processing system 1. The process section 11 has various single wafer processing units for processing the wafer 14 sequentially one by one. These processing units may be arranged in predetermined positions of multiple stages, for example, within first process unit group 31 (G1), second process unit group 32 (G2), third process unit group 33 (G3), fourth process unit group 34 (G4) and fifth process unit group 35 (G5). The interface section 12 is interposed between the process section 11 and one or more other processing systems (not shown), and is configured to transfer substrates between the process section 11 and the other processing systems.

As shown in FIG. 2, the load/unload section 10 includes a plurality of projections 20a, which are formed on the cassette table 20 and used to orient each of the plurality of cassettes 13 relative to the process section 11. Each of the cassettes 13 mounted on the cassette table 20 has a load/unload opening 9 facing the process section 11. The load/unload section 10 further includes a first sub-arm mechanism 21 that is responsible for loading/unloading the wafer W into/from each of the cassettes 13. In the system shown in FIG. 2, the first sub-arm mechanism 21 is positioned to access processing units contained within the third process unit group 33 (G3).

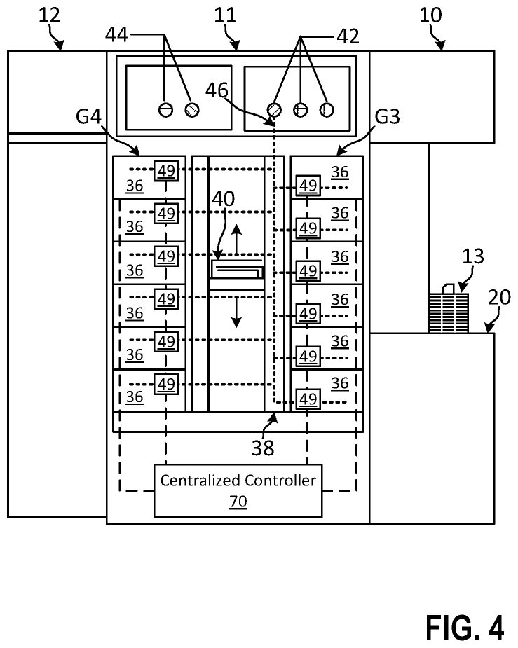

As shown in FIGS. 2 and 4, the process section 11 includes the process unit groups G1-G5 and a main arm mechanism 22. The main arm mechanism 22 is liftably arranged at the center of the process section within a cylindrical supporting body 38. The main arm mechanism 22 has a liftable wafer transporting system 40 for transporting substrates to/from the processing units contained within the process unit groups G1-G5, which are arranged around the main arm mechanism 22.

As shown in FIG. 2, processing units belonging to the first process unit group 31 (G1) and the second process unit groups 32 (G2) are arranged at a front portion 2 of the substrate processing system 1. Processing units belonging to the third process unit group 33 (G3) are arranged next to the load/unload section 10. Processing units belonging to the fourth process unit group 34 (G4) are arranged next to the interface section 12. Processing units belonging to the fifth process unit group 35 (G5) are arranged in a back portion 3 of the substrate processing system 1. The fifth process unit group 35 (G5) is slidably shifted in the Y-axis direction along a guide rail 25 to enable maintenance operations to be applied to the main arm mechanism 22 from the backside.

As shown in FIG. 2, the interface section 12 includes a movable pick-up cassette (PCR) 15 and a non-movable buffer cassette (BR) 16 arranged at the front side of the interface section 12. At the center portion of the interface section 12, a second sub-arm mechanism 24 movable independently in the X and Z directions is provided for gaining access to both cassettes 15 and 16. In addition, the second sub-arm mechanism 24 is rotatable around the Z-axis by an angle of θ and is designed to be able to access not only to the fourth process unit group 34 (G4), but also to a wafer transfer table (not shown).

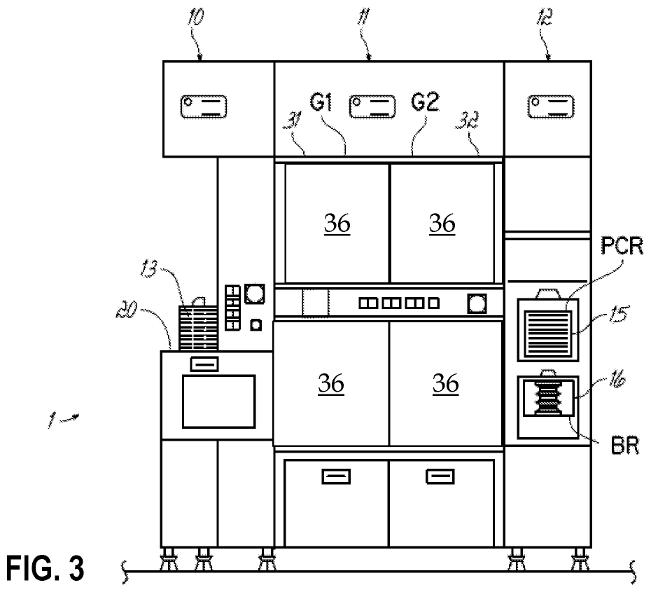

The process unit groups G1-G5 included within the substrate processing system 1 may generally contain any number, type and/or arrangement of processing units. Examples of processing units that may be included within the process unit groups G1-G5 include for example, but are not limited to, a resist coating unit, a developing unit, a cooling unit, an alignment unit, an adhesion unit, an extension unit, a baking unit, an etch unit, a deposition unit, a sputtering unit, an oxidation unit, etc. In the example substrate processing system 1 shown in FIGS. 2-4, process unit groups G1 and G2 each include a pair of processing units 36 which are stacked vertically near the front portion 2 of the substrate processing system 1 (see, FIG. 3). Process unit groups G3 and G4 each include a plurality (e.g., 12) of processing units 36 stacked vertically alongside the cylindrical supporting body 38 of the main arm mechanism 22 (see, FIG. 4). Although not shown in FIGS. 2-4, process unit group G5 may also include one or more processing units 36 arranged near the back portion 3 of the substrate processing system 1. Although a particular number of processing units 36 are illustrated in the drawings, it is recognized that each of the process unit groups G1-G5 may include any number and/or combination of the example processing units mentioned above.

As described above, liquids and/or gases may be used within at least some of the processing units 36 to perform a process on a substrate. For example, liquids may be supplied to some processing units and gases to other processing units, while some processing units may receive both. The liquids and gases supplied to, and used within, the processing units 36 are often stored outside of the substrate processing system 1 within supply vessels, routed through external supply lines (comprising various liquid and gas inlet pipes, valves, and/or sensors), and connected to external connectors provided, for example, on a backside of the substrate processing system 1. Alternatively, the external connectors could be provided on the top or bottom or other locations of the substrate processing system 1.

As noted above, conventional substrate processing systems typically include a large number of external connectors on the backside (or top or bottom) of the system for supplying liquids and/or gases to the processing units contained therein. For example, some conventional substrate processing systems include a separate external connector for each liquid and gas supplied for each liquid and gas individually supplied to each of the processing units. When installing such systems, customers are faced with high installation costs, due to the high number of individual components (e.g., liquid/gas inlet pipes, valves, sensors, filters, etc.) and installation labor required to connect external liquid and gas sources to the large number of external connectors typically provided on the system and it's processing modules.

In order to reduce installation and maintenance costs, the substrate processing system 1 shown in FIGS. 2-4 provides only one external connector on the backside (or the top or bottom) of the system for each liquid and gas, which is used within the system to process a substrate, and provides internal distribution lines within the substrate processing system 1 to route the liquids and gases to an appropriate one of the processing units 36. In addition to improving the installation and maintenance costs and time, such techniques also provide a variety of technical benefits. For example, the incoming gas pressure provided to a system may be more tightly controlled through the use of a single gas regulator. Further, in the case of toxic or flammable liquids, a number of smaller individual liquid sources or bottles may be reduced. This may allow for a more constant liquid flow supply and less frequent source changes, both factors which provide improved safety when operating and maintaining the substrate processing system. Further, reducing the number of components reduces the number of points of failure, providing both manufacturing costs and safety improvement. Finally, such external connections may be supplied through sources provided through confined working spaces of subfloor areas. Minimizing the safety risks associated with working in such confined spaces by minimizing the number of external connections is another advantage of the techniques described herein.

In the example embodiment shown in FIGS. 2 and 4, three external connectors 42 are provided on the backside of substrate processing system 1 for receiving gases from three different gas sources (e.g., gas source 41, gas source 43 and gas source 45), and two external connectors 44 are provided on the backside of substrate processing system 1 for receiving liquids from two different liquid sources (e.g., liquid source 47 and liquid source 48). Compared to the conventional substrate processing system 100, the substrate processing system 1 shown in FIGS. 2-4 significantly reduces the number of external connectors (e.g., 5 vs. 65) provided on the substrate processing system. In addition to reducing installation and maintenance costs, the reduced number of external connectors on substrate processing system 1 enables fewer gas and liquid sources (41, 43, 45, 47, 48) to be used, and further enables bulk supply vessels to be used instead of a plurality of smaller supply vessels. This allows for a more consistent liquid and gas supply with less frequent source changes. Although a certain number of external connectors (i.e., 5), gas sources (i.e., 3) and liquid sources (i.e., 2) are depicted in FIGS. 2 and 4, the substrate processing system 1 and methods described herein are not limited to any particular number, and may generally include one external connector for each liquid/gas source, which is used within the system to process a substrate.

In some embodiments, one or more external connectors 42 and one or more external connectors 44 may be provided on the backside of the substrate processing system 1 near the top of the system, as shown in FIG. 4. It is noted, however, that external connectors 42 and external connectors 44 are not restricted to the example arrangement shown in FIG. 4 and may be alternatively arranged anywhere along the backside, top, bottom, or elsewhere of the substrate processing system 1 without departing from the scope of the present disclosure.

In the present disclosure, a plurality of internal distribution lines 46 are contained within the substrate processing system 1 for routing liquids and gases to the processing units 36 contained therein. While only one internal distribution line 46 is illustrated in FIG. 4 for purposes of drawing clarity, it is recognized that a separate internal distribution line 46 would be included within substrate processing system 1 for each external connector 42 and each external connector 44 provided on the system. In the example provided in FIG. 4, five (5) internal distributions lines 46 would be included within substrate processing system 1 for routing liquids and gases from the three external connectors 42 and the two external connectors 44 to the processing units 36.

The internal distribution lines 46 may generally be configured to route liquids and gases to one or more of the processing units 36 contained within the substrate processing system 1. In the example provided in FIG. 4, one internal distribution line 46 is coupled for routing a gas from one of the external connectors 42 to all processing units 36 included within process unit groups G3 and G4. In other embodiments (not shown), the internal distribution line 46 shown in FIG. 4 may be coupled to route the gas to only a subset of the processing units 36 included within process unit groups G3 and G4. In some embodiments (not shown), the internal distribution line 46 shown in FIG. 4 may be further coupled to route the gas to one or more processing units 36 contained within other process unit groups (e.g., G1, G2 and/or G5). In some embodiments (not shown), the internal distribution line 46 shown in FIG. 4 may be coupled to route the gas to all processing units 36 included within the substrate processing system 1.

The depiction provided in FIG. 4 represents only one example of an internal distribution line 46 that may be provided within the substrate processing system 1 for routing a liquid or a gas to one or more processing units 36 contained within the system. In some embodiments, one or more internal distribution lines may be coupled to route a liquid or a gas to only a subset of the processing units 36 contained within the substrate processing system 1. For example, one or more internal distribution lines may be coupled to route a liquid or a gas to only the processing units 36 that utilize the liquid or the gas within the processing unit to process a substrate.

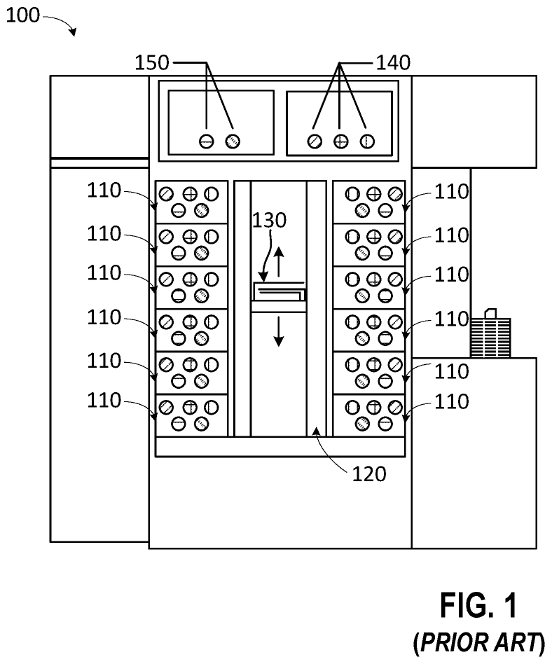

The substrate processing system 1 shown in FIGS. 2-4 improves upon conventional substrate processing systems (such as the substrate processing system 100 shown in FIG. 1), in one respect, by reducing the number of external connectors, which are provided on the backside (or the top or bottom) of the system for receiving liquids and gases from external liquid and gas sources. Instead of providing a separate external connector for each liquid and gas individually supplied to each of the processing units, the substrate processing system 1 shown in FIGS. 2-4 provides only one external connector for each liquid/gas, which is used by the system to process a substrate. In order to support a reduced number of external connectors, the substrate processing system 1 shown in FIGS. 2-4 utilizes the three dimensional space within the system housing to provide internal distribution lines 46 for routing the liquids and gases to the appropriate processing units 36. The use of internal distribution lines 46 provides significant savings in terms of customer installation costs and time, savings for external connector and component costs, savings for maintenance costs and time, improved technical performance and improved safety factors for operation and maintenance, and therefore, provides a distinct advantage to the customer. The costs savings provided by the techniques herein are significant and will be dependent upon the number of external connections being replaced. For example, for a system previously having five process modules and front end external connectors, up to four external connectors per gas or liquid source may be removed, providing significant savings. For a system having nine modules or front end external connectors, up to eight external connectors per gas or liquid source may be removed. Systems having even more modules (for example a sixteen process module system), would have even a higher percentage of external connectors removed. In general for typical process systems, the connection costs may be reduced 50% to 90% utilizing the techniques described herein.

In addition, the substrate processing system 1 shown in FIGS. 2-4 improves upon conventional substrate processing systems by providing a centralized controller 70 that uses sensor feedback to control the supply of liquids and gases to the substrate processing system 1. The centralized controller 70 receives sensor data from a plurality of sensors 49, which are coupled for monitoring the liquids and gases supplied from the liquid and gas sources (41, 43, 45, 47, 48) to the substrate processing system 1. As described in more detail below, the centralized controller 70 uses the sensor data received from the sensors 49 to control the liquid and gases, which are supplied from the liquid and gas sources (41, 43, 45, 47, 48) to the external connectors 42, 44 and/or to the individual processing units 36.

Sensors 49 are provided for monitoring the liquids and gases supplied from the liquid and gas sources (41, 43, 45, 47, 48) to the substrate processing system 1 and for generating sensor data based on said monitoring. A variety of sensors 49 may be utilized for generating a variety of sensor data. In one embodiment, for example, sensors 49 may include flow sensors for monitoring the flow rate and/or pressure sensors for monitoring the pressure of the supplied liquids and gases. Other types of sensors may also be included within sensors 49.

Sensors 49 may be coupled to the substrate processing system 1 at a variety of different locations. In some embodiments, sensors 49 may be coupled to the external liquid and gas supply lines for monitoring the liquids and gases supplied from the liquid and gas sources (41, 43, 45, 47, 48) to the external connectors 40 and 42, as shown in FIG. 2. Although illustrated within the external supply lines, sensors 49 may be alternatively coupled to, or provided within, the external connectors 40 and 42. In other embodiments, sensors 49 may be coupled to the internal distribution lines 46 for monitoring the liquids and gases supplied to each of the individual processing units 36, as shown in FIG. 4. In further embodiments, sensors 49 may be coupled to: (a) the external liquid and gas supply lines (or the external connectors 40, 42) for monitoring the liquids and gases supplied to the external connectors 40 and 42, and (b) the internal distribution lines 46 for monitoring the liquids and gases supplied to the individual processing units 36.

The centralized controller 70 is communicatively coupled to the sensors 49 and to the individual processing units 36. In some embodiments, the centralized controller 70 may be located outside of the substrate processing system 1 as shown, for example, in FIG. 2. In other embodiments, the centralized controller 70 may be located within the substrate processing system 1, as shown in FIG. 4. In either embodiment, the centralized controller 70 may be coupled to the sensors 49 and the processing units 36 via a wired or wireless connection.

The centralized controller 70 receives sensor data from the sensors 49 and uses the sensor data to control the supply of liquid and gases from the liquid and gas sources (41, 43, 45, 47, 48) to the external connectors 42, 44 and/or the individual processing units 36. By utilizing a centralized controller 70, the substrate processing system 1 improves chamber to chamber matching by eliminating differences in controller offsets that tend to occur when separate controllers are used to control the supply of liquid and gases to the individual processing units.

In some embodiments, the centralized controller 70 may use the sensor data to account for the supply needs of the individual processing units 36. For example, one or more of the processing units 36 may have different liquid/gas supply needs than the other processing units 36. When sensors 49 are provided within the processing units 110, the centralized controller 70 can monitor the sensor data provided by the sensors 49 and separately adjust or control the flow rate, pressure, etc. of the liquid(s) and/or gas(es) supplied to each individual processing unit 36, based on the liquid/gas supply needs of the individual processing unit.

In some embodiments, the centralized controller 70 may use artificial intelligence (AI) (or machine learning) to control the supply of liquids and/or gases to the processing units 36 based on the sensor data received from the sensors 49. For example, the centralized controller 70 could monitor the sensor data received from the sensors 49 and use AI to adjust one or more variables or operational parameters (e.g., flow rate, pressure, etc.) of the liquid and gas sources (41, 43, 45, 47, 48) to account for supply changes that occur over time. When multiple processing units 36 are using the same liquid or gas at the same time, for example, the AI component of the centralized controller 70 may account for time varying liquid/gas demands by monitoring the sensor data provided by the sensors 49 over time, and adjusting one or more variables or operational parameters (e.g., flow rate, pressure, etc.) of the liquid and gas sources (41, 43, 45, 47, 48) in real-time to account for the time varying demands.

By utilizing artificial intelligence (AI), centralized controller 70 improves controllability of the liquid and gas sources by predicting and controlling the liquid/gas usage per line or source. Sensors 49 provide the sensor data needed for the feedback loop, which the AI uses to predictively control liquid/gas flow to each processing unit. Although examples are provided above for illustrative purposes, the centralized controller 70 may use artificial intelligence to predictively control the liquid/gas supply in other ways.

It is recognized that the centralized controller 70 can be implemented in a wide variety of manners. In one example, the centralized controller 70 may be implemented as a computer having at least one non-transitory computer-readable medium for storing program instructions and at least one processor for executing the stored program instructions to implement the functionality described herein. In another example, the centralized controller 70 may include one or more programmable integrated circuits, which are programmed to provide the functionality described herein. For example, the centralized controller 70 may include one or more processors (e.g., microprocessor, microcontroller, central processing unit, etc.), programmable logic devices (e.g., complex programmable logic device (CPLD)), field programmable gate array (FPGA), etc.), and/or other programmable integrated circuits, which can be programmed with software or other programming instructions to implement the functionality described herein. The software or other programming instructions can be stored in one or more non-transitory computer-readable mediums (e.g., memory storage devices, FLASH memory, DRAM memory, reprogrammable storage devices, hard drives, floppy disks, DVDs, CD-ROMs, etc.). When executed by the programmable integrated circuits, the software or other programming instructions cause the programmable integrated circuits to perform the processes, functions, and/or capabilities described herein. Other variations could also be implemented.

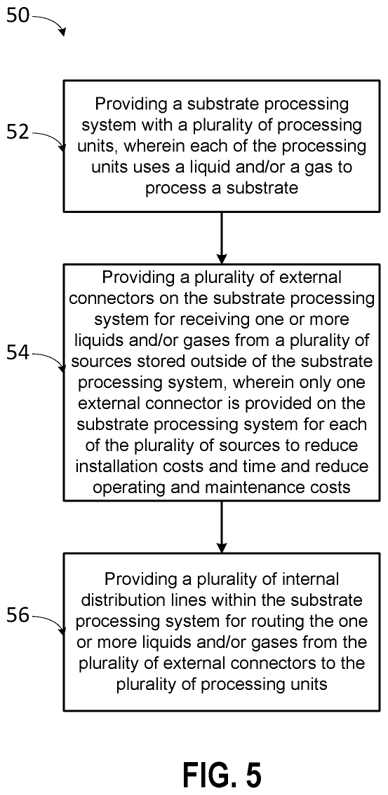

FIG. 5 illustrates one embodiment of a method 50 that may be used to reduce a number of external connectors provided on a substrate processing system having a plurality of processing units. In step 52, the method 50 includes providing the substrate processing system with the plurality of processing units, wherein each of the processing units uses a liquid and/or a gas to process a substrate. In step 54, the method 50 includes providing a plurality of external connectors on the substrate processing system for receiving liquids and gases from a plurality of sources stored outside of the substrate processing system. As noted above and shown in FIGS. 2 and 4, only one external connector is provided on the substrate processing system for each of the plurality of sources to reduce installation costs and time and reduce operating and maintenance costs. In step 56, the method 50 includes providing a plurality of internal distribution lines within the substrate processing system for routing the liquids and the gases from the plurality of external connectors to the plurality of processing units.

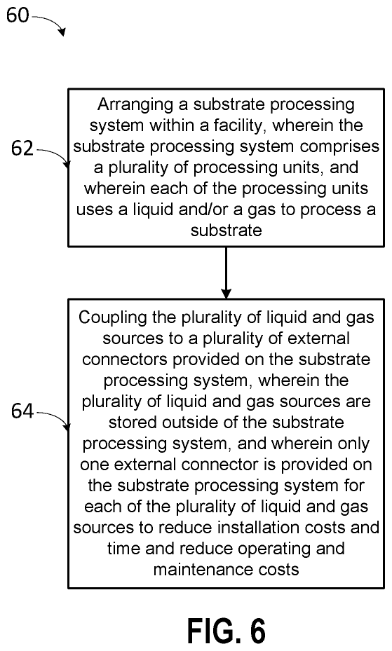

FIG. 6 illustrates one embodiment of a method 60 to couple a substrate processing system to a plurality of liquid and gas sources. In step 62, the method 60 includes arranging the substrate processing system within a facility, wherein the substrate processing system comprises a plurality of processing units, and wherein each of the processing units uses a liquid and/or a gas to process a substrate. In step 64, the method 60 includes coupling the plurality of liquid and gas sources to a plurality of external connectors provided on the substrate processing system, wherein the plurality of liquid and gas sources are stored outside of the substrate processing system, and wherein only one external connector is provided on the substrate processing system for each of the liquid and gas sources to reduce installation costs and time and reduce operating and maintenance costs.

It will be recognized that the system and method embodiments disclosed herein may be utilized during the processing of a wide range of substrates. The substrate may be any substrate for which the patterning of the substrate is desirable. For example, in one embodiment, the substrate may be a semiconductor substrate having one or more semiconductor processing layers (all of which together may comprise the substrate) formed thereon. Thus, in one embodiment, the substrate may be a semiconductor substrate that has been subject to multiple semiconductor processing steps which yield a wide variety of structures and layers, all of which are known in the substrate processing art, and which may be considered to be part of the substrate. For example, in one embodiment, the substrate may be a semiconductor wafer having one or more semiconductor processing layers formed thereon. The concepts disclosed herein may be utilized at any stage of the substrate process flow, for example, any of the numerous photolithography steps which may be utilized to form a completed substrate.

Further modifications and alternative embodiments of the inventions will be apparent to those skilled in the art in view of this description. Accordingly, this description is to be construed as illustrative only and is for the purpose of teaching those skilled in the art the manner of carrying out the inventions. It is to be understood that the forms and method of the inventions herein shown and described are to be taken as presently preferred embodiments. Equivalent techniques may be substituted for those illustrated and described herein and certain features of the inventions may be utilized independently of the use of other features, all as would be apparent to one skilled in the art after having the benefit of this description of the inventions.

What is claimed is:

1. A substrate processing system, comprising:
a plurality of external connectors provided on the substrate processing system for receiving one or more liquids and/or gases, which are supplied from a plurality of sources to the plurality of external connectors via a plurality of external supply lines, where the plurality of sources are stored outside of the substrate processing system, and wherein only one external connector is provided on the substrate processing system for each of the plurality of sources to reduce installation costs and time and reduce operating and maintenance costs;
a plurality of processing units, each coupled to receive at least one of the one or more liquids and/or the gases for processing a substrate; and
a plurality of internal distribution lines provided within the substrate processing system for routing the one or more liquids and/or the gases from the plurality of external connectors to the plurality of processing units.

2. The substrate processing system of claim 1, wherein a separate one of the plurality of internal distribution lines is provided within the substrate processing system for each of the plurality of external connectors.

3. The substrate processing system of claim 1, wherein the plurality of internal distribution lines are each coupled to route a first liquid or a first gas from one of the plurality of external connectors to one or more of the processing units contained within the substrate processing system.

4. The substrate processing system of claim 1, wherein the plurality of internal distribution lines are each coupled to route a first liquid or a first gas from one of the plurality of external connectors to only the processing units that utilize the first liquid or the first gas to process the substrate.

5. The substrate processing system of claim 1, wherein the substrate processing system receives one or more liquids and one or more gases from the plurality of sources stored outside of the substrate processing system, wherein the one or more liquids is one or more of a resist solution, a develop solution, a quench solution, a rinse solution, a deposition solution, or an etch solution, and wherein the one or more gases is one or more of nitrogen, argon, hydrogen, helium, oxygen, ammonia, chlorine, dichlorosilane, hydrogen chloride, hydrogen fluoride, silicon tetrachloride, or fluorocarbons.

6. The substrate processing system of claim 1, further comprising:
a plurality of sensors coupled to monitor the one or more liquids and/or gases supplied from the plurality of sources and generate sensor data based on said monitoring; and
a centralized controller coupled to receive the sensor data from the plurality of sensors, and configured to use the sensor data to control supply of the one or more liquids and/or gases to the plurality of external connectors and/or to the plurality of processing units.

7. The substrate processing system of claim 6, wherein the plurality of sensors are coupled to one or more of:
the plurality of external supply lines, or the plurality of external connectors, to monitor the one or more liquids and/or gases supplied from the plurality of sources to the plurality of external connectors; and
the plurality of internal distribution lines to monitor the one or more liquids and/or gases routed from the plurality of external connectors to the plurality of processing units.

8. The substrate processing system of claim 6, wherein the centralized controller uses the sensor data to control a flow rate or a pressure of the one or more liquids and/or gases supplied to each processing unit, based on liquid/gas supply needs of the processing unit.

9. The substrate processing system of claim 6, wherein the centralized controller uses artificial intelligence to control supply of the one or more liquids and/or gases to the plurality of processing units based on the sensor data received from the plurality of sensors.

10. A method to reduce a number of external connectors provided on a substrate processing system having a plurality of processing units, the method comprising:
providing the substrate processing system with the plurality of processing units, wherein each of the processing units uses a liquid and/or a gas to process a substrate; and
providing a plurality of external connectors on the substrate processing system for receiving one or more liquids and/or gases from a plurality of sources stored outside of the substrate processing system, wherein only one external connector is provided on the substrate processing system for each of the plurality of sources to reduce installation costs and time and reduce operating and maintenance costs.

11. The method of claim 10, further comprising providing a plurality of internal distribution lines within the substrate processing system for routing the one or more liquids and/or gases from the plurality of external connectors to the plurality of processing units.

12. The method of claim 11, wherein said providing the plurality of internal distribution lines comprises providing a separate internal distribution line within the substrate processing system for each external connector.

13. The method of claim 11, further comprising coupling each of the internal distribution lines to one or more of the processing units contained within the substrate processing system.

14. The method of claim 11, further comprising:
providing the substrate processing system with a plurality of sensors and a centralized controller;
monitoring the one or more liquids and/or gases supplied from the plurality of sources and generating sensor data based on said monitoring, wherein
said monitoring and said generating are performed by the plurality of sensors; and
receiving the sensor data from the plurality of sensors and using the sensor data to control supply of the one or more liquids and/or gases to the plurality of external connectors and/or to the plurality of processing units, wherein said receiving the sensor data and said using the sensor data are performed by the centralized controller.

15. The method of claim 14, further comprising using the sensor data to predict and control supply of the one or more liquids and/or gases to the plurality of external connectors over time and/or based liquid/gas supply needs of the plurality of processing units.

16. A method to couple a substrate processing system to a plurality of liquid and gas sources, the method comprising:
arranging the substrate processing system within a facility, wherein the substrate processing system comprises a plurality of processing units, and wherein each of the processing units uses a liquid and/or a gas to process a substrate; and
coupling the plurality of liquid and gas sources to a plurality of external connectors provided on the substrate processing system, wherein the plurality of liquid and gas sources are stored outside of the substrate processing system; and
wherein only one external connector is provided on the substrate processing system for each of the plurality of liquid and gas sources to reduce installation costs and time and reduce operating and maintenance costs.

17. The method of claim 16, wherein said coupling comprises coupling, via an external supply line, each of the plurality of liquid and gas sources to a different one of the plurality of external connectors for supplying a liquid or a gas thereto.

18. The method of claim 17, wherein said coupling comprises coupling one or more sensors to the external supply line for monitoring the liquid or the gas supplied to the different one of the plurality of external connectors.

19. The method of claim 16, further comprising providing a plurality of internal distribution lines within the substrate processing system for routing one or more liquids and gases from the plurality of external connectors to the plurality of processing units.

20. The method of claim 19, further comprising coupling one or more sensors to each of the plurality of internal distribution lines for monitoring the one or more liquids and gases routed from the plurality of external connectors to the plurality of processing units.
